(19) United States
(12) Patent Application Publication
(10) Pub. No.: US 2023/0223909 A1
(43) Pub. Date: Jul. 13, 2023

(54) ACOUSTIC WAVE DEVICE AND ACOUSTIC-WAVE-DEVICE MANUFACTURING METHOD

(71) Applicant: Murata Manufacturing Co., Ltd., Nagaokakyo-shi (JP)

(72) Inventors: Kazunori INOUE, Nagaokakyo-shi (JP); Sho NAGATOMO, Nagaokakyo-shi (JP)

(21) Appl. No.: 18/121,634

(22) Filed: Mar. 15, 2023

Related U.S. Application Data
(63) Continuation of application No. PCT/JP2021/034205, filed on Sep. 16, 2021.
(60) Provisional application No. 63/079,544, filed on Sep. 17, 2020.
(60) Provisional application No. 63/122,965, filed on Dec. 9, 2020.

(51) Int. Cl. H03H 3/04; H03H 3/08

(52) U.S. Cl. CPC H03H 3/04; H03H 3/08; H03H 2003/0428

(57) ABSTRACT

An acoustic wave device includes a support substrate, a piezoelectric layer, and first and second electrodes. The piezoelectric layer overlaps the support substrate in a first direction. The first and second electrodes extend over at least a first major surface of the piezoelectric layer. The first and second electrodes face each other and are at different potentials. A space between a second major surface of the piezoelectric layer and the support substrate is covered by the piezoelectric layer. The first and second electrodes each include an overlap portion overlapping the space in the first direction and a non-overlap portion not overlapping the space in the first direction. At least part of the support substrate includes an attenuation layer and overlaps a region between the non-overlap portions of the first and second electrodes in plan view. The attenuation layer and the support substrate have different crystallinities.

### CROSS REFERENCE TO RELATED APPLICATIONS

This application claims the benefit of priority to Provisional Application No. 63/122,965 filed on Dec. 9, 2020 and Provisional Application No. 63/079,544 filed on Sep. 17, 2020 and is a Continuation Application of PCT Application No. PCT/JP2021/034205 filed on Sep. 16, 2021. The entire contents of each application are hereby incorporated herein by reference.

### BACKGROUND OF THE INVENTION

### 1. Field of the Invention

The present disclosure relates to an acoustic wave device with a piezoelectric layer including lithium niobate or lithium tantalate, and an acoustic-wave-device manufacturing method.

### 2. Description of the Related Art

Japanese Unexamined Patent Application Publication No. 2012-257019 describes an acoustic wave device.

### SUMMARY OF THE INVENTION

For the acoustic wave device described in Japanese Unexamined Patent Application Publication No. 2012-257019, a demand exists to reduce ripples in frequency characteristics.

Preferred embodiments of the present invention provide acoustic wave devices and acoustic-wave-device manufacturing methods that each reduce ripples in frequency characteristics.

An acoustic wave device according to an aspect of an example embodiment of the present disclosure includes a support substrate, a piezoelectric layer overlapping the support substrate as seen in a first direction, and a first electrode and a second electrode extending over at least a first major surface of the piezoelectric layer, the first electrode and the second electrode facing each other and being at mutually different potentials. A space exists between a second major surface of the piezoelectric layer, and the support substrate, the second major surface being opposite to the first major surface. The space is at least partially covered by the piezoelectric layer. The first electrode and the second electrode each include an overlap portion and a non-overlap portion, the overlap portion overlapping the space in the first direction, the non-overlap portion not overlapping the space in the first direction. At least part of the support substrate includes an attenuation layer, the at least part of the support substrate overlapping a region located between the non-overlap portion of the first electrode and the non-overlap portion of the second electrode in plan view, the attenuation layer having a crystallinity different from a crystallinity of the support substrate.

An acoustic wave device according to an aspect of an example embodiment of the present disclosure includes a support substrate, a piezoelectric layer overlapping the support substrate as seen in a first direction, a first resonator extending over at least a first major surface of the piezoelectric layer, and a second resonator extending over at least the first major surface of the piezoelectric layer, the second resonator being at a location different from a location of the first resonator. The first resonator includes a first space opposite to the first major surface and at or adjacent to a second major surface of the piezoelectric layer, and a first electrode including a first overlap portion and a first non-overlap portion, the first overlap portion overlapping the first space in the first direction, the first non-overlap portion not overlapping the first space in the first direction. The second resonator includes a second space opposite to the first major surface and at or adjacent to the second major surface of the piezoelectric layer, and a second electrode including a second overlap portion and a second non-overlap portion, the second overlap portion overlapping the second space in the first direction, the second non-overlap portion not overlapping the second space in the first direction. The second space is at a location different from a location of the first space. The first electrode and the second electrode face each other, and are at mutually different potentials. At least part of the support substrate includes an attenuation layer, the at least part of the support substrate overlapping a region located between the first non-overlap portion and the second non-overlap portion in plan view, the attenuation layer having a crystallinity different from a crystallinity of the support substrate.

An acoustic-wave-device manufacturing method according to an aspect of an example embodiment of the present disclosure includes forming an attenuation layer inside a support substrate including a first surface and a second surface, the attenuation layer having a crystallinity different from a crystallinity of the support substrate, the attenuation layer being formed by ion implantation applied to the second surface of the support substrate, stacking a piezoelectric layer over the first surface of the support substrate such that the piezoelectric layer covers a hollow, and forming a first electrode film and a second electrode film over a surface of the piezoelectric layer opposite to the first surface of the support substrate. The forming the attenuation-layer, the stacking the piezoelectric-layer, and the forming the electrode-film are performed in this order.

An acoustic-wave-device manufacturing method according to an aspect of an example embodiment of the present disclosure includes forming an attenuation layer inside a support substrate including a first surface and a second surface, the attenuation layer having a crystallinity different from a crystallinity of the support substrate, the attenuation layer being formed by laser irradiation applied to the second surface of the support substrate, stacking a piezoelectric layer over the first surface of the support substrate such that the piezoelectric layer covers a hollow, and forming a first electrode film and a second electrode film over a surface of the piezoelectric layer opposite to the first surface of the support substrate. The forming the attenuation-layer, the stacking the piezoelectric-layer, and the forming the electrode-film are performed in this order.

An acoustic wave device according to an aspect of an example embodiment of the present disclosure includes a support substrate, a piezoelectric layer overlapping the support substrate as seen in a first direction, and a first electrode and a second electrode extending over at least a first major surface of the piezoelectric layer, the first electrode and the second electrode facing each other and being at mutually different potentials. A space exists between a second major surface of the piezoelectric layer, and the support substrate, the second major surface being opposite to the first major surface. The space is at least partially covered by the piezoelectric layer. The first electrode and the second electrode each include an overlap portion and a non-overlap portion, the overlap portion overlapping the space in the first direction, the non-overlap portion not overlapping the space in the first direction. At least part of the support substrate includes a void, the at least part of the support substrate overlapping a region located between the non-overlap portion of the first electrode and the non-overlap portion of the second electrode in plan view, the void being defined by a partially hollowed out portion of the support substrate.

An acoustic wave device according to an aspect of an example embodiment of the present disclosure includes a support substrate, a piezoelectric layer overlapping the support substrate as seen in a first direction, a first resonator extending over at least a first major surface of the piezoelectric layer, and a second resonator extending over at least the first major surface of the piezoelectric layer, the second resonator being at a location different from a location of the first resonator. The first resonator includes a first space opposite to the first major surface and at or adjacent to a second major surface of the piezoelectric layer, and a first electrode including a first overlap portion and a first non-overlap portion, the first overlap portion overlapping the first space in the first direction, the first non-overlap portion not overlapping the first space in the first direction. The second resonator includes a second space opposite to the first major surface and at or adjacent to the second major surface of the piezoelectric layer, and a second electrode including a second overlap portion and a second non-overlap portion, the second overlap portion overlapping the second space in the first direction, the second non-overlap portion not overlapping the second space in the first direction. The second space is at a location different from a location of the first space. The first electrode and the second electrode face each other, and are at mutually different potentials. At least part of the support substrate includes a void, the at least part of the support substrate overlapping a region located between the first non-overlap portion and the second non-overlap portion in plan view, the void being defined by a partially hollowed out portion of the support substrate.

Example embodiments of the present disclosure reduce ripples in frequency characteristics.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1A is a perspective view of an acoustic wave device according to a first preferred embodiment of the present invention.

FIG. 1B is a plan view of an arrangement of electrodes according to the first preferred embodiment of the present invention.

FIG. 2 is a cross-sectional view taken along a line II-II in FIG. 1A.

FIG. 3A is a schematic cross-sectional illustration for explaining Lamb waves propagating in a piezoelectric layer according to Comparative Example.

FIG. 3B is a schematic cross-sectional illustration for explaining bulk waves in first-order thickness shear mode that propagate in a piezoelectric layer according to the first preferred embodiment of the present invention.

FIG. 4 is a schematic cross-sectional illustration for explaining the amplitude directions of bulk waves in first-order thickness shear mode that propagate in the piezoelectric layer according to the first preferred embodiment of the present invention.

FIG. 5 illustrates an example of the resonance characteristics of the acoustic wave device according to the first preferred embodiment of the present invention.

FIG. 6 illustrates, for the acoustic wave device according to the first preferred embodiment of the present invention, the relationship between d/2p, and the fractional band width of the acoustic wave device serving as a resonator, where p is the center-to-center distance between mutually adjacent electrodes or the mean center-to-center distance, and d is the mean thickness of the piezoelectric layer.

FIG. 7 is a plan view of an example of the acoustic wave device according to the first preferred embodiment of the present invention that includes one pair of electrodes.

FIG. 8 is a partially cut-away perspective view of an acoustic wave device according to a modification of the first preferred embodiment of the present invention.

FIG. 9 is a plan view of an acoustic wave device according to Comparative Example.

FIG. 10 is a cross-sectional view taken along a line X-X in FIG. 9.

FIG. 11A is an illustration for explaining frequency characteristics according to Comparative Example.

FIG. 11B is an illustration for explaining part of the frequency characteristics illustrated in FIG. 11A.

FIG. 12 is a plan view of the acoustic wave device according to the first preferred embodiment of the present invention.

FIG. 13 is a cross-sectional view taken along a line XIII-XIII in FIG. 12.

FIG. 14 is an illustration for explaining a manufacturing method according to the first preferred embodiment of the present invention.

FIG. 15 is a cross-sectional view of an acoustic wave device according to a second preferred embodiment of the present invention.

FIG. 16 is an illustration for explaining a manufacturing method according to the second preferred embodiment of the present invention.

FIG. 17 is a cross-sectional view of an acoustic wave device according to a modification of the second preferred embodiment of the present invention.

FIG. 18 is a cross-sectional view of an acoustic wave device according to a third preferred embodiment of the present invention.

FIG. 19 is a cross-sectional view of an acoustic wave device according to a modification of the third preferred embodiment of the present invention.

FIG. 20 is a cross-sectional view of an acoustic wave device according to a fourth preferred embodiment of the present invention.

FIG. 21 is a cross-sectional view of an acoustic wave device according to a fifth preferred embodiment of the present invention.

FIG. 22 is a cross-sectional view of an acoustic wave device according to a sixth preferred embodiment of the present invention.

FIG. 23A schematically illustrates an acoustic reflected wave according to the first preferred embodiment of the present invention.

FIG. 23B schematically illustrates acoustic reflected waves according to the sixth preferred embodiment of the present invention.

FIG. 24 schematically illustrates attenuation layers of the acoustic wave device according to the sixth preferred embodiment of the present invention.

FIG. 25 is an illustration for explaining, for the acoustic wave device according to the sixth preferred embodiment of the present invention, the relationship between the thickness of an attenuation layer and ripple level.

FIG. 26 is an illustration for explaining acoustic impedance for the acoustic wave device according to the sixth preferred embodiment of the present invention.

FIG. 27 is an illustration for explaining, for the acoustic wave device according to the sixth preferred embodiment of the present invention, the relationship between the material of an attenuation layer and transverse-wave acoustic velocity.

FIG. 28 is a cross-sectional view of an acoustic wave device according to a modification of the sixth preferred embodiment of the present invention.

FIG. 29 is a cross-sectional view of an acoustic wave device according to a modification of a seventh preferred embodiment of the present invention.

FIG. 30 is an illustration for explaining, for an acoustic wave device according to an eighth preferred embodiment of the present invention, the relationship between d/2p, metallization ratio MR, and fractional band width.

FIG. 31 illustrates, for an acoustic wave device according to a ninth preferred embodiment of the present invention, a map of fractional band width with respect to the Euler angles (0°, θ, ψ) of LiNbO₃ with d/p set as close to zero as possible.

### DETAILED DESCRIPTION OF THE PREFERRED EMBODIMENTS

Preferred embodiments of the present disclosure will be described below in detail with reference to the drawings. These preferred embodiments, however, are not intended to be limiting of the present disclosure. The disclosed preferred embodiments are intended to be illustrative only. Modifications that allow features to be partially combined or replaced with each other between different preferred embodiments, and matters described with reference to the second and subsequent preferred embodiments that are identical to those described with reference to the first preferred embodiment will not be described in further detail, and the following description will focus only on differences. In particular, the same or similar operational effects provided by the same or similar features will not be described for each individual preferred embodiment.

### First Preferred Embodiment

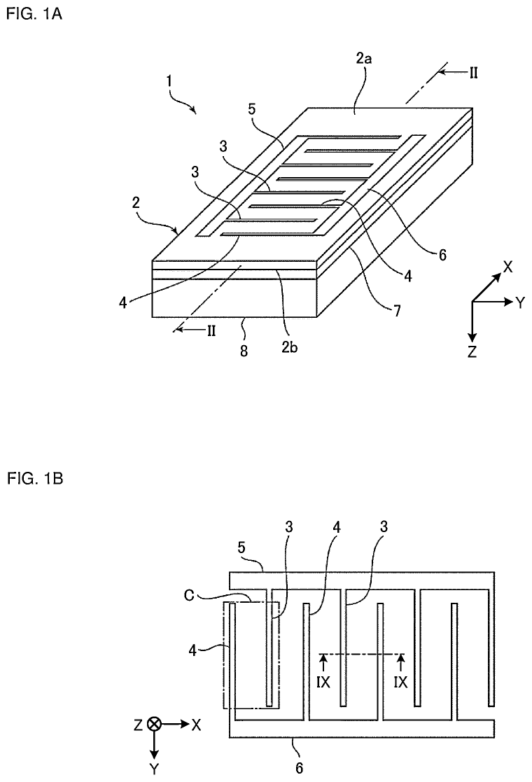

FIG. 1A is a perspective view of an acoustic wave device according to a first preferred embodiment. FIG. 1B is a plan view of an arrangement of electrodes according to the first preferred embodiment.

An acoustic wave device 1 according to the first preferred embodiment includes a piezoelectric layer 2 made of LiNbO₃. The piezoelectric layer 2 may be made of LiTaO₃. The LiNbO₃ or LiTaO₃ used has a Z-cut angle according to the first preferred embodiment. The LiNbO₃ or LiTaO₃ used may have a rotated Y-cut angle or an X-cut angle. Preferred orientations of propagation are Y-propagation and X-propagation of about ±30°, for example.

Although the thickness of the piezoelectric layer 2 is not particularly limited, from the viewpoint of effectively exciting a first-order thickness shear mode, the piezoelectric layer 2 preferably has a thickness of greater than or equal to about 50 nm and less than or equal to about 1000 nm, for example.

The piezoelectric layer 2 has a first major surface 2a and a second major surface 2b that are opposite to each other in a Z-direction. An electrode 3 and an electrode 4 are disposed over the first major surface 2a.

The electrode 3 corresponds to an example of a “first electrode”, and the electrode 4 corresponds to an example of a “second electrode”. In FIGS. 1A and 1B, a plurality of electrodes 3 (hereinafter referred to in the singular as “electrode 3” for convenience unless otherwise indicated) are connected with a first busbar 5. A plurality of electrodes 4 (hereinafter referred to in the singular as “electrode 4” for convenience unless otherwise indicated) are connected with a second busbar 6. Each electrode 3 and each electrode 4 are interdigitated with each other.

Each of the electrode 3 and the electrode 4 is rectangular or substantially rectangular in shape, and has a longitudinal direction. In a direction orthogonal to the longitudinal direction, the electrode 3, and the electrode 4 adjacent to the electrode 3 face each other. The longitudinal direction of the electrodes 3 and 4, and a direction orthogonal to the longitudinal direction of the electrodes 3 and 4 are each a direction that crosses the thickness direction of the piezoelectric layer 2. It can thus be said that the electrode 3, and the electrode 4 adjacent to the electrode 3 face each other in a direction that crosses the thickness direction of the piezoelectric layer 2. In the following description of the first preferred embodiment, it will be sometimes assumed that the thickness direction of the piezoelectric layer 2 is a Z-direction (or a first direction), a direction orthogonal to the longitudinal direction of the electrodes 3 and 4 is an X-direction (or a second direction), and the longitudinal direction of the electrodes 3 and 4 is a Y-direction (or a third direction).

The longitudinal direction of the electrodes 3 and 4 may be interchanged with the direction orthogonal to the longitudinal direction of the electrodes 3 and 4 illustrated in FIGS. 1A and 1B. That is, the electrode 3 and the electrode 4 may extend in a direction in which the first busbar 5 and the second busbar 6 extend in FIGS. 1A and 1B. In that case, the first busbar 5 and the second busbar 6 extend in a direction in which the electrode 3 and the electrode 4 extend in FIGS. 1A and 1B. A plurality of pairs of mutually adjacent electrodes 3 and 4, each pair including the electrode 3 connected with one potential and the electrode 4 connected with the other potential, are disposed in the direction orthogonal to the longitudinal direction of the electrodes 3 and 4.

When it is stated herein that the electrode 3 and the electrode 4 are adjacent to each other, it is not meant that the electrode 3 and the electrode 4 are disposed in direct contact with each other but it is meant that the electrode 3 and the electrode 4 are disposed with a spacing therebetween. Further, if the electrode 3 and the electrode 4 are adjacent to each other, no electrode connected with a hot electrode or a ground electrode, such as another electrode 3 or 4, is present between the adjacent electrodes 3 and 4. The number of such electrode pairs does not necessary be an integer but may be 1.5, 2.5, or other non-integer.

The center-to-center distance, that is, the pitch between the electrodes 3 and 4 is preferably greater than or equal to about 1 μm and less than or equal to about 10 μm, for example. The center-to-center distance between the electrodes 3 and 4 refers to the distance between the center of the width dimension of the electrode 3 in a direction orthogonal to the longitudinal direction of the electrode 3, and the center of the width dimension of the electrode 4 in a direction orthogonal to the longitudinal direction of the electrode 4.

Further, if at least one of the number of electrodes 3 and the number of electrodes 4 is more than one (i.e., if, with the electrode 3 and the electrode 4 defined as one pair of electrodes, there are 1.5 or more pairs of electrodes), the center-to-center distance between the electrodes 3 and 4 refers to the mean of the center-to-center distances of mutually adjacent electrodes 3 and 4 among the 1.5 or more pairs of electrodes 3 and 4.

The width of each of the electrodes 3 and 4, that is, the dimension of each of the electrodes 3 and 4 in a direction in which the electrodes 3 and 4 face each other is preferably greater than or equal to about 150 nm and less than or equal to about 1000 nm, for example. The center-to-center distance between the electrodes 3 and 4 refers to the distance between the center of the dimension (width dimension) of the electrode 3 in the direction orthogonal to the longitudinal direction of the electrode 3, and the center of the dimension (width dimension) of the electrode 4 in the direction orthogonal to the longitudinal direction of the electrode 4.

Since the piezoelectric layer according to the first preferred embodiment is a Z-cut piezoelectric layer, the direction orthogonal to the longitudinal direction of the electrodes 3 and 4 is a direction orthogonal to the polarization direction of the piezoelectric layer 2. This, however, does not hold if a piezoelectric with another cut-angle is used as the piezoelectric layer 2. As used herein, the term “orthogonal” may encompass not only strictly orthogonal but also substantially orthogonal (i.e., when the direction orthogonal to the longitudinal direction of the electrodes 3 and 4, and the polarization direction make an angle of, for example, approximately 90°±10°).

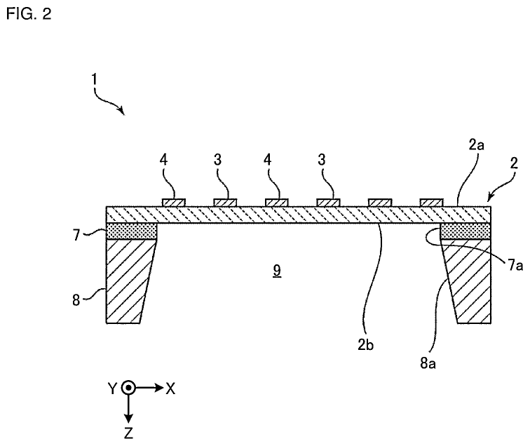

A support member 8 is stacked over the second major surface 2b of the piezoelectric layer 2 with an intermediate layer 7 interposed therebetween. The intermediate layer 7 and the support member 8 have a frame shape, and respectively have a cavity 7a and a cavity 8a as illustrated in FIG. 2. Due to the configuration mentioned above, a hollow (air gap) 9 is formed.

The hollow 9 is provided so that vibration of an excitation region C of the piezoelectric layer 2 is not prevented. Accordingly, the support member 8 is stacked over the second major surface 2b with the intermediate layer 7 interposed therebetween, at a location not overlapping an area where at least one pair of electrodes 3 and 4 is present. No intermediate layer 7 may be provided. Accordingly, the support member 8 can be stacked directly or indirectly over the second major surface 2b of the piezoelectric layer 2.

The intermediate layer 7 is an insulating layer, and made of silicon oxide. The intermediate layer 7 may, however, be made of any suitable insulating material other than silicon oxide, such as silicon oxynitride or alumina.

The support member 8 is also referred to as support substrate, and made of Si. The plane orientation of a surface of Si near the piezoelectric layer 2 may be (100), or may be (110) or (111). Preferably, the Si used has a high resistivity greater than or equal to about 4 kΩ, for example. It is to be noted, however, that the support member 8 may as well be made of any suitable insulating material or semiconductor material. Examples of suitable materials of the support member 8 may include piezoelectrics such as aluminum oxide, lithium tantalate, lithium niobate, and quartz, various ceramics such as alumina, magnesia, sapphire, silicon nitride, aluminum nitride, silicon carbide, zirconia, cordierite, mullite, steatite, and forsterite, dielectrics such as diamond and glass, and semiconductors such as gallium nitride.

The electrodes 3, the electrodes 4, the first busbar 5, and the second busbar 6 are each made of any suitable metal or alloy such as Al or AlCu alloy. According to the first preferred embodiment, each of the electrode 3, the electrode 4, the first busbar 5, and the second busbar 6 is a stack of an Al film over a Ti film. It is to be noted, however, that an adhesion layer other than a Ti film may be used.

In driving, an alternating-current voltage is applied between the electrodes 3 and the electrodes 4. More specifically, an alternating-current voltage is applied between the first busbar 5 and the second busbar 6. This makes it possible to provide resonance characteristics using bulk waves in first-order thickness shear mode excited in the piezoelectric layer 2.

The acoustic wave device 1 is designed such that d/p is less than or equal to, for example, about 0.5, where d is the thickness of the piezoelectric layer 2, and p is the center-to-center distance between any mutually adjacent electrodes 3 and 4 among a plurality of pairs of electrodes 3 and 4. This makes it possible to effectively excite the bulk waves in first-order thickness shear mode mentioned above, and consequently provide resonance characteristics. More preferably, d/p is less than or equal to about 0.24, for example, in which case further improved resonance characteristics can be provided.

It is to be noted that if at least one of the number of electrodes 3 and the number of electrodes 4 is more than one as with the first preferred embodiment, that is, if, with the electrode 3 and the electrode 4 defined as one pair of electrodes, there are 1.5 or more pairs of electrodes 3 and 4, the center-to-center distance p between mutually adjacent electrodes 3 and 4 refers to the mean of the center-to-center distances of the respective pairs of mutually adjacent electrodes 3 and 4.

The above-mentioned configuration of the acoustic wave device 1 according to the first preferred embodiment helps to reduce a decrease in Q-factor, even if the number of pairs of electrodes 3 and 4 is reduced to achieve miniaturization. This is because the resulting resonator does not require a reflector on each side, and thus has no insertion loss. The reason why no reflector is required as mentioned above is because bulk waves in first-order thickness shear mode are used.

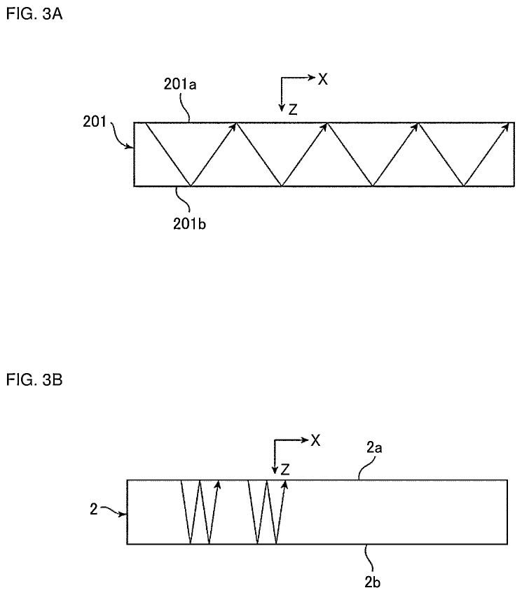

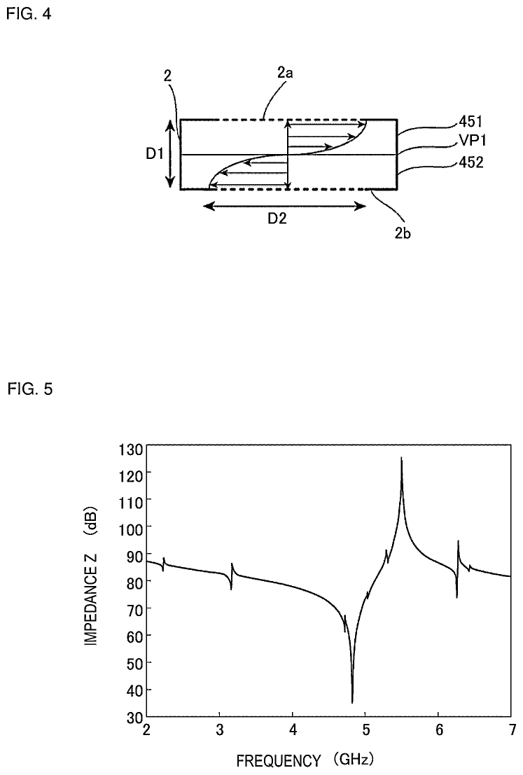

FIG. 3A is a schematic cross-sectional illustration for explaining Lamb waves propagating in a piezoelectric layer according to Comparative Example. FIG. 3B is a schematic cross-sectional illustration for explaining bulk waves in first-order thickness shear mode that propagate in the piezoelectric layer according to the first preferred embodiment. FIG. 4 is a schematic cross-sectional illustration for explaining the amplitude directions of bulk waves in first-order thickness shear mode that propagate in the piezoelectric layer according to the first preferred embodiment.

FIG. 3A illustrates an acoustic wave device like the one described in Japanese Unexamined Patent Application Publication No. 2012-257019, with Lamb waves propagating in the piezoelectric layer. As illustrated in FIG. 3A, the waves propagate within a piezoelectric layer 201 as indicated by arrows. The piezoelectric layer 201 has a first major surface 201a, and a second major surface 201b. The thickness direction connecting the first major surface 201a and the second major surface 201b is defined as the Z-direction. The X-direction refers to a direction in which the fingers of an interdigital transducer (IDT) electrode are arranged. As illustrated in FIG. 3A, Lamb waves propagate in the X-direction. Although the piezoelectric layer 201 vibrates as a whole due to the Lamb waves being plate waves, since the waves propagate in the X-direction, a reflector is disposed on each side to provide resonance characteristics. This results in wave propagation loss. Therefore, an attempt for miniaturization, that is, a reduction in the number of pairs of electrode fingers results in a decrease in Q-factor.

By contrast, with the acoustic wave device according to the first preferred embodiment, vibration displacement occurs in the thickness shear direction as illustrated in FIG. 3B. This results in the waves propagating substantially in the direction connecting the first major surface 2a and the second major surface 2b of the piezoelectric layer 2, that is, in the Z-direction, to achieve resonance. That is, the waves have an extremely small X-direction component relative to their Z-direction component. Since the wave propagation in the Z-direction provides the resonance characteristics, no reflector is required. This means that no propagation loss due to wave propagation through the reflector occurs. This helps to reduce a decrease in Q-factor, even if the number of pairs of electrodes 3 and 4 is reduced in an attempt to achieve further miniaturization.

As illustrated in FIG. 4, the amplitude direction of bulk waves in first-order thickness shear mode is opposite between a first region 451 and a second region 452, which are included in the excitation region C of the piezoelectric layer 2 (see FIG. 1B). FIG. 4 schematically illustrates bulk waves generated upon application of a voltage between the electrode 3 and the electrode 4 such that the electrode 4 is at a higher potential than the electrode 3. The first region 451 is a portion of the excitation region C located between a virtual plane VP1 and the first major surface 2a, the virtual plane VP1 being orthogonal to the thickness direction of the piezoelectric layer 2 and dividing the piezoelectric layer 2 into two regions. The second region 452 is a portion of the excitation region C located between the virtual plane VP1 and the second major surface 2b.

As described above, the acoustic wave device 1 includes at least one pair of electrodes including the electrode 3 and the electrode 4. Since the acoustic wave device 1 is not designed for wave propagation in the X-direction, the acoustic wave device 1 does not necessarily need to include a plurality of such electrode pairs each including the electrode 3 and the electrode 4. That is, the acoustic wave device 1 may simply include at least one pair of electrodes.

For example, the electrode 3 is an electrode to be connected with a hot potential, and the electrode 4 is an electrode to be connected with a ground potential. Alternatively, however, the electrode 3 may be connected with a ground potential, and the electrode 4 may be connected with a hot potential. According to the first preferred embodiment, at least one pair of electrodes includes an electrode to be connected with a hot potential or an electrode to be connected with a ground potential as described above, and no floating electrode is provided.

FIG. 5 illustrates an example of the resonance characteristics of the acoustic wave device according to the first preferred embodiment. The acoustic wave device 1 with the resonance characteristics illustrated in FIG. 5 has design parameters described below.

Piezoelectric layer 2: LiNbO₃ with Euler angles (0°, 0°, 90°)

Thickness of piezoelectric layer 2: 400 nm

Length of excitation region C (see FIG. 1B): 40 μm

Number of electrode pairs each including the electrode 3 and the electrode 4: 21

Center-to-center distance (pitch) p between electrodes 3 and 4: 3 μm

Width of electrodes 3 and 4: 500 nm d/p: 0.133

Intermediate layer 7: silicon oxide film with thickness of 1 μm

Support member 8: Si

The excitation region C (see FIG. 1B) refers to a region where the electrodes 3 and 4 overlap each other when viewed in the X-direction, which is a direction orthogonal to the longitudinal direction of the electrodes 3 and 4. The length of the excitation region C refers to a dimension of the excitation region C in the longitudinal direction of the electrodes 3 and 4.

According to the first preferred embodiment, the center-to-center distance is set equal between all pairs of electrodes 3 and 4. That is, the electrodes 3 and 4 are disposed at equal pitches.

As can be appreciated from FIG. 5, improved resonance characteristics with a fractional band width of about 12.5% are obtained, even though no reflector is provided.

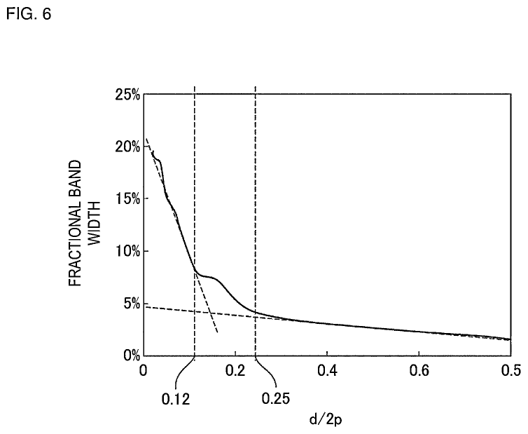

According to the first preferred embodiment, d/p is less than or equal to about 0.5, more preferably less than or equal to about 0.24, where d is the thickness of the piezoelectric layer 2, and p is the center-to-center distance between the electrode 3 and the electrode 4. This is explained below with reference to FIG. 6.

A plurality of acoustic wave devices are obtained in the same manner as with the acoustic wave device having the resonant characteristics illustrated in FIG. 5, but with varying values of d/2p. FIG. 6 illustrates, for the acoustic wave device according to the first preferred embodiment, the relationship between d/2p, and the fractional band width of the acoustic wave device serving as a resonator, where p is the center-to-center distance between mutually adjacent electrodes or the mean center-to-center distance, and d is the mean thickness of the piezoelectric layer.

As illustrated in FIG. 6, when d/2p exceeds about 0.25, that is, when d/p>about 0.5, the fractional band width remains below 5% even as d/p is adjusted. By contrast, when d/2p≤about 0.25, that is, when d/p≤about 0.5, varying d/p within this range makes it possible to provide a fractional band width of greater than or equal to 5%, that is, a resonator with a high coupling coefficient. When d/2p is less than or equal to about 0.12, that is, when d/p is less than or equal to about 0.24, the fractional band width can be increased to be greater than or equal to 7%. In addition, adjusting d/p within this range makes it possible to provide a resonator with an even greater fractional band width, and consequently with an even higher coupling coefficient. It can therefore be appreciated that setting d/p less than or equal to about 0.5 makes it possible to provide a resonator with a high coupling coefficient that uses the bulk waves in first-order thickness shear mode mentioned above.

It is to be noted that the at least one pair of electrodes mentioned above may be one pair of electrodes, in which case the value of p mentioned above is the center-to-center distance between mutually adjacent electrodes 3 and 4. If there are 1.5 or more pairs of electrodes, the mean of the center-to-center distances of mutually adjacent electrodes 3 and 4 may be defined as p.

For example, if the piezoelectric layer 2 has thickness variations, its averaged thickness may be used.

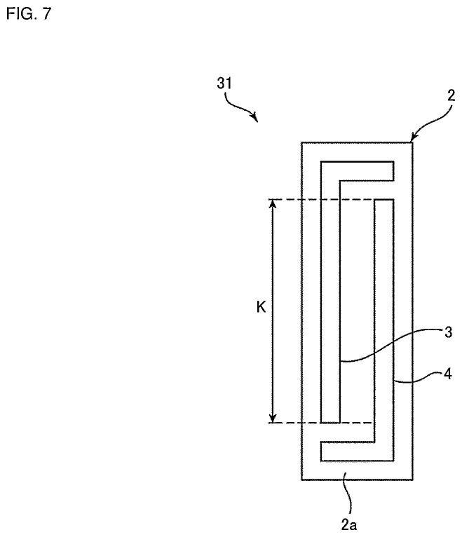

FIG. 7 is a plan view of an example of the acoustic wave device according to the first preferred embodiment that includes one pair of electrodes. An acoustic wave device 31 includes one pair of electrodes 3 and 4 disposed over the first major surface 2a of the piezoelectric layer 2. In FIG. 7, K represents intersecting width. As previously mentioned, an acoustic wave device according to an example embodiment of the present disclosure may include one pair of electrodes. In this case as well, bulk waves in first-order thickness shear mode can be effectively excited if the value of d/p mentioned above is less than or equal to about 0.5, for example.

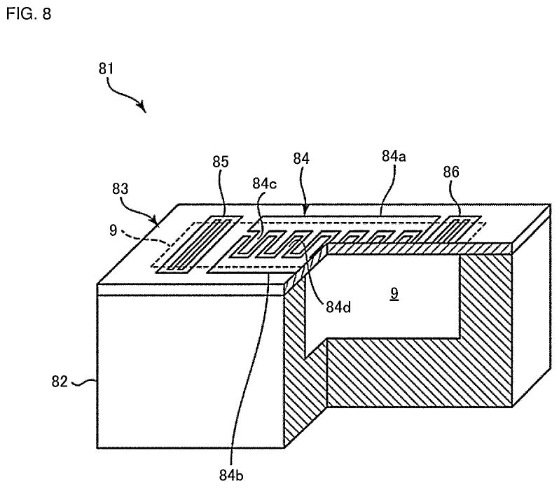

FIG. 8 is a partially cut-away perspective view of an acoustic wave device according to a modification of the first preferred embodiment. An acoustic wave device 81 includes a support substrate 82. The support substrate 82 has a recess that opens at the top. A piezoelectric layer 83 is stacked over the support substrate 82. Due to the configuration mentioned above, the hollow 9 is formed. An IDT electrode 84 is disposed above the hollow 9 and over the piezoelectric layer 83. Reflectors 85 and 86 are disposed beside opposite sides of the IDT electrode 84 in the direction of acoustic wave propagation. In FIG. 8, the peripheral edges of the hollow 9 are represented by broken lines. In this case, the IDT electrode 84 includes a first busbar 84a, a second busbar 84b, a plurality of electrodes 84c serving as first electrode fingers, and a plurality of electrodes 84d serving as second electrode fingers. The electrodes 84c are connected with the first busbar 84a. The electrodes 84d are connected with the second busbar 84b. Each electrode 84c and each electrode 84d are interdigitated with each other.

In the acoustic wave device 81, Lamb waves, which are plate waves, are excited through application of an alternating-current electric field to the IDT electrode 84 disposed over the hollow 9. The presence of the reflectors 85 and 86 beside opposite sides of the IDT electrode 84 makes it possible to provide resonance characteristics due to the Lamb waves.

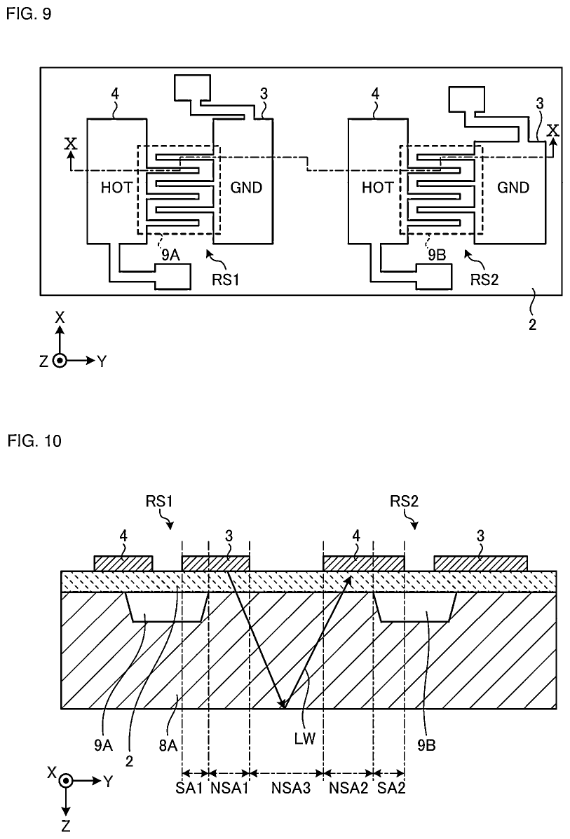

FIG. 9 is a plan view of an acoustic wave device according to Comparative Example. FIG. 10 is a cross-sectional view taken along a line X-X in FIG. 9. As illustrated in FIGS. 9 and 10, in the acoustic wave device according to Comparative Example, a single support member 8A supports a first resonator RS1 and a second resonator RS2.

The acoustic wave device illustrated in FIGS. 9 and 10 includes the support member 8A, and a piezoelectric layer with the first major surface 2a and the second major surface 2b. Electrodes are disposed over the first major surface 2a, and hollows 9A and 9B are located near the second major surface 2b.

As seen in the Z-direction, the first electrode 3 of the first resonator RS1 extends over an overlap portion SA1 that overlaps the hollow 9A, and a non-overlap portion NSA1 that does not overlap the hollow 9A. As seen in the Z-direction, the second electrode 4 of the second resonator RS2 extends over an overlap region SA2 that overlaps the hollow 9B, and a non-overlap portion NSA2 that does not overlap the hollow 9B.

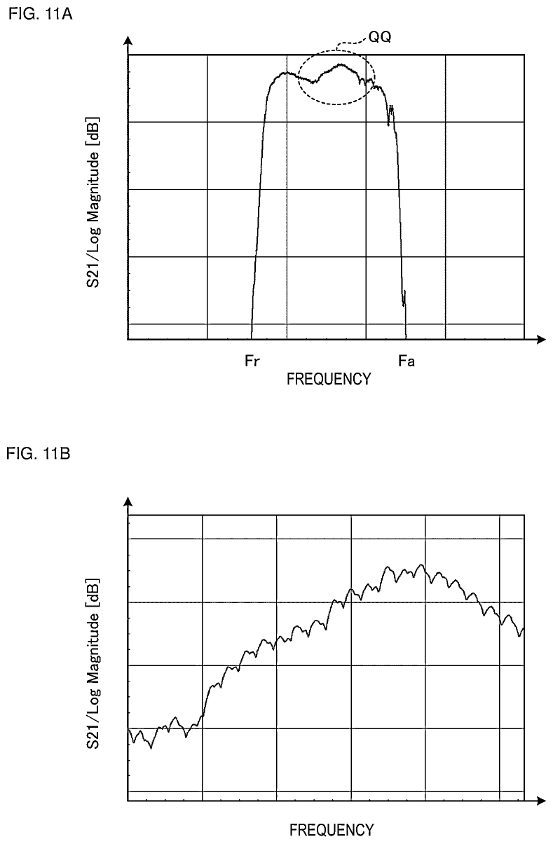

The region between the non-overlap portion NSA1 of the first electrode 3, and the non-overlap portion NSA2 of the second electrode 4 is defined as a region NSA3. As seen in plan view in the Z-direction, the first electrode 3 of the first resonator RS1, and the second electrode 4 of the second resonator RS2 are disposed with the region NSA3 interposed therebetween. As illustrated in FIG. 10, a leaky wave LW due to leakage of a wave excited by the electrode 3 of the first resonator RS1 may potentially be reflected by the region NSA3 of the support member 8A and propagate to the electrode 4 of the second resonator RS2. FIG. 11A is an illustration for explaining frequency characteristics according to Comparative Example. FIG. 11B is an illustration for explaining part of the frequency characteristics illustrated in FIG. 11A. In FIGS. 11A and 11B, the vertical axis represents bandpass characteristics [dB], and the horizontal axis represents frequency. A band of frequencies between a resonant frequency Fr and an anti-resonant frequency Fa, which are illustrated in FIG. 11A, is herein referred to as pass band. FIG. 11B is an enlarged illustration of a pass band QQ illustrated in FIG. 11A. Within the pass band in FIGS. 11A and 11B, insertion loss is depicted, and outside the pass band in FIG. 11A, attenuation is depicted.

As illustrated in FIG. 11B, the acoustic wave device according to Comparative Example has a large number of ripples in the filter pass band QQ due to the leaky wave LW. This can lead to degradation of filter characteristics.

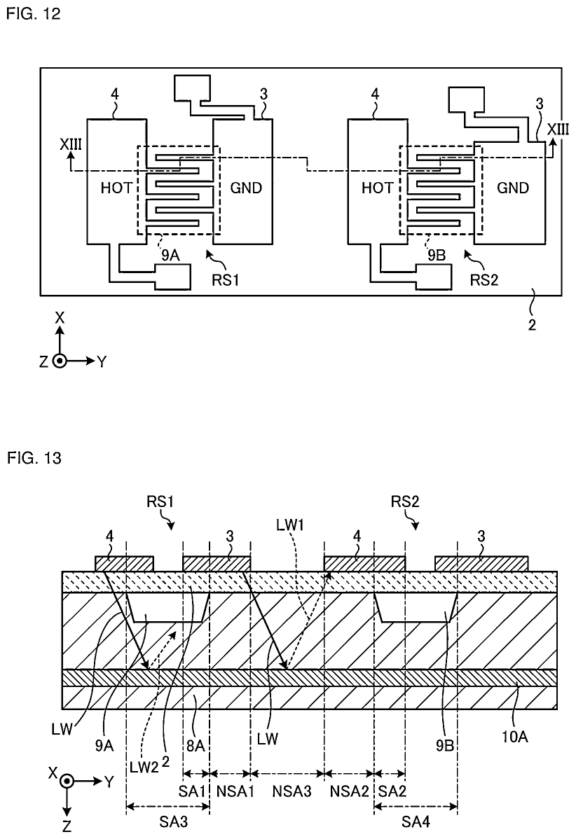

FIG. 12 is a plan view of the acoustic wave device according to the first preferred embodiment. FIG. 13 is a cross-sectional view taken along a line XII-XII in FIG. 12. As illustrated in FIGS. 12 and 13, in the acoustic wave device according to the first preferred embodiment, a single support member 8A supports the first resonator RS1 and the second resonator RS2. The second resonator RS2 is at a location different from that of the first resonator RS1.

The acoustic wave device illustrated in FIGS. 12 and 13 includes the support member 8A, and the piezoelectric layer 2 with the first major surface 2a and the second major surface 2b. The first electrode 3 and the second electrode 4 are disposed over the first major surface 2a, and the hollows 9A and 9B are located near the second major surface 2b. The hollow 9B is disposed in the Y-direction relative to the hollow 9A. One of the first electrode 3 of the first resonator RS1, and the second electrode 4 of the second resonator RS2 is a hot electrode, and the other is a ground electrode. The first electrode 3 of the first resonator RS1, and the second electrode 4 of the second resonator RS2 have mutually different potentials. According to the first preferred embodiment, the first electrode 3 of the first resonator RS1 is a ground electrode, and the second electrode 4 of the second resonator RS2 is a hot electrode.

As seen in the Z-direction, the first electrode 3 of the first resonator RS1 extends over the overlap region SA1 that overlaps the hollow 9A, and the non-overlap portion NSA1 that does not overlap the hollow 9A. As seen in the Z-direction, the second electrode 4 of the second resonator RS2 extends over the overlap region SA2 that overlaps the hollow 9B, and the non-overlap portion NSA2 that does not overlap the hollow 9B.

The region between the non-overlap portion NSA1 of the first electrode 3, and the non-overlap portion NSA2 of the second electrode 4 is defined as the region NSA3. As seen in plan view in the Z-direction, the first electrode 3 of the first resonator RS1, and the second electrode 4 of the second resonator RS2 are disposed with the region NSA3 interposed therebetween.

An attenuation layer 10A, which differs in crystallinity from the support member 8A, is disposed in a portion of the support member 8A that overlaps the region NSA3. According to the first preferred embodiment, the attenuation layer 10A is at a depth of, for example, greater than or equal to about 20 μm and less than or equal to about 50 μm from the back side of the support member 8A, which is a side opposite to the front side where the piezoelectric layer 2 is present. The attenuation layer 10A exists over the entire X-Y plane. It can thus be said that the attenuation layer 10A with a crystallinity different from the crystallinity of the support member 8A is disposed in a portion of the support member 8A that overlaps the region NSA3.

If the support member 8A is made of Si, the attenuation layer 10A is, for example, an amorphous silicon layer or a polysilicon layer. For example, a leaky wave LW due to leakage of a wave excited by the electrode 3 of the first resonator RS1 undergoes attenuation in the attenuation layer 10A located in the region NSA3 of the support member 8A. Consequently, a reflected wave LW1 reflected by the attenuation layer 10A undergoes attenuation, which reduces the intensity of the reflected wave LW1 that propagates to the electrode 4 of the second resonator RS2.

As seen in the Z-direction, the attenuation layer 10A exists also in a region SA3, which overlaps the hollow 9A, and in a region SA4, which overlaps the hollow 9B. For example, a leaky wave LW due to leakage of a wave excited by the electrode 4 of the first resonator RS1 undergoes attenuation in the attenuation layer 10A in the region SA3. Consequently, a reflected wave LW2 reflected by the attenuation layer 10A undergoes attenuation, which reduces the intensity of the reflected wave LW2 that propagates to the electrode 3 of the first resonator RS1.

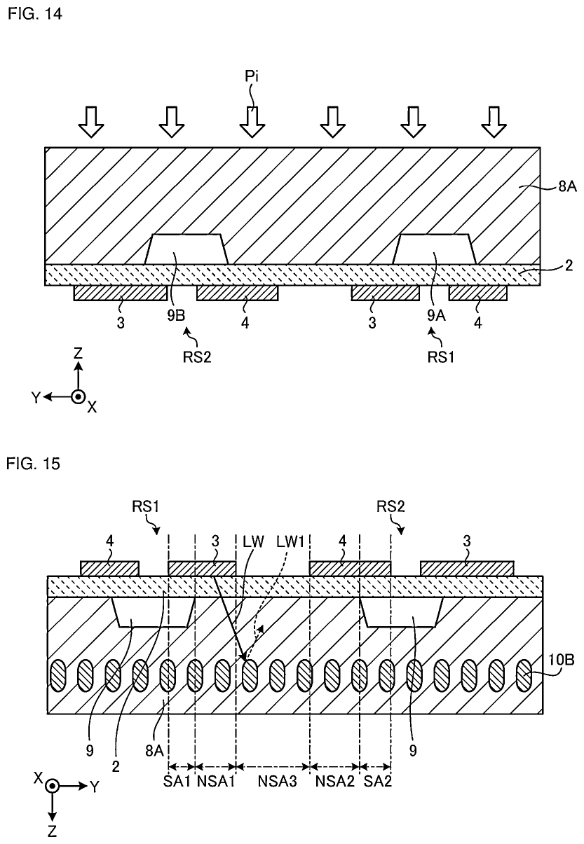

An acoustic-wave-device manufacturing method according to the first preferred embodiment will be described below. FIG. 14 is an illustration for explaining the manufacturing method according to the first preferred embodiment.

### Piezoelectric-Layer Stacking Step

The hollow 9A and the hollow 9B are formed at a first surface of the support member 8A. Subsequently, the piezoelectric layer 2 is stacked over the first surface of the support member 8A so as to cover the hollow 9A and the hollow 9B.

### Electrode-Film Forming Step

After the piezoelectric-layer stacking step, a film of the first electrode 3 and a film of the second electrode 4 are formed by sputtering or other methods over a first major surface of the piezoelectric layer 2, which is located opposite to the first surface of the support member 8A.

### Attenuation-Layer Forming Step

As illustrated in FIG. 14, after the electrode-film forming step, hydrogen ion implantation Pi is applied to a second surface of the support member 8A opposite to the first surface. A portion of the support member 8A that has undergone the hydrogen ion implantation Pi becomes the attenuation layer 10A that differs in crystallinity from a portion of the support member 8A that does not undergo the hydrogen ion implantation.

In the acoustic-wave-device manufacturing method described above, the piezoelectric-layer stacking step, the electrode-film forming step, and the attenuation-layer forming step are performed in this order. In the acoustic-wave-device manufacturing method according to the first preferred embodiment, however, these steps are not necessarily performed in the above-mentioned order.

### Attenuation-Layer Forming Step

First, with the support member 8A being in the state of a substrate with no hollows 9A and 9B formed therein, hydrogen ion implantation Pi is applied to the second surface of the support member 8A opposite to the first surface. A portion of the support member 8A that has undergone the hydrogen ion implantation Pi becomes the attenuation layer 10A that differs in crystallinity from a portion of the support member 8A that does not undergo the hydrogen ion implantation.

### Piezoelectric-Layer Stacking Step

After the attenuation-layer forming step, the hollow 9A and the hollow 9B are formed at the first surface of the support member 8A. Subsequently, the piezoelectric layer 2 is stacked over the first surface of the support member 8A so as to cover the hollow 9A and the hollow 9B.

### Electrode-Film Forming Step

After the piezoelectric-layer stacking step, a film of the first electrode 3 and a film of the second electrode 4 are formed by sputtering or other methods over a first major surface of the piezoelectric layer 2, which is located opposite to the first surface of the support member 8A.

In the other acoustic-wave-device manufacturing method described above, the attenuation-layer forming step, the piezoelectric-layer stacking step, and the electrode-film forming step are performed in this order. This helps to reduce degradation of the piezoelectric layer 2 or the electrode films at the attenuation-layer forming step, which in turn makes it possible to omit a process for protecting the piezoelectric layer 2 or the electrode films.

### Second Preferred Embodiment

FIG. 15 is a cross-sectional view of an acoustic wave device according to a second preferred embodiment. FIG. 15 is a cross-sectional view taken along the line XII-XII in FIG. 12. Features according to the second preferred embodiment that are identical to those according to the first preferred embodiment will be designated by the same reference signs and will not be described in further detail.

Attenuation layers 10B are provided by reforming of a portion of the support member 8A that overlaps the region NSA3. According to the second preferred embodiment, the attenuation layers 10B are at a depth of, for example, greater than or equal to about 20 μm and less than or equal to about 50 μm from the back side of the support member 8A. The attenuation layers 10B are dotted over the entire X-Y plane. It can thus be said that the attenuation layers 10B are disposed in a portion of the support member 8A that overlaps the region NSA3.

For example, a leaky wave LW due to leakage of a wave excited by the electrode 3 of the first resonator RS1 undergoes attenuation in the attenuation layers 10B located in the region NSA3 of the support member 8A. Consequently, a reflected wave LW1 reflected by the attenuation layers 10B undergoes attenuation, which reduces the intensity of the reflected wave LW1 that propagates to the electrode 4 of the second resonator RS2.

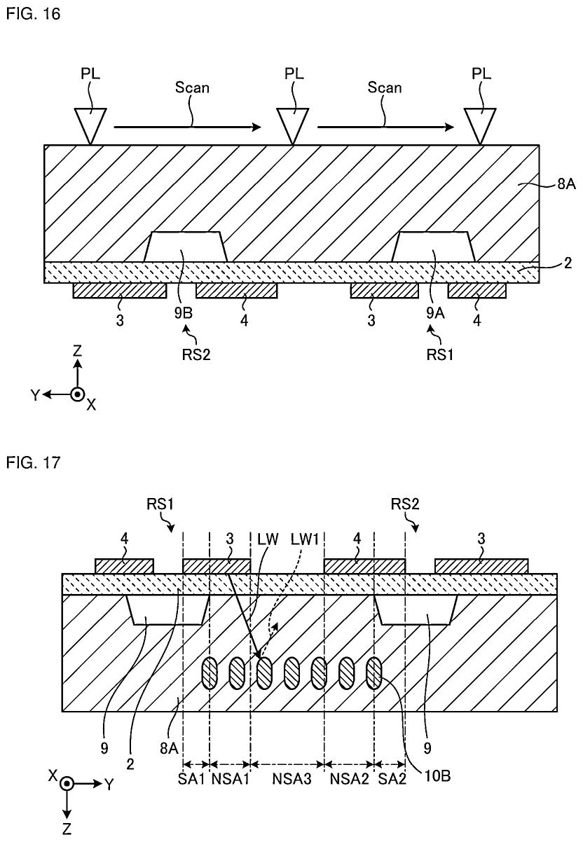

An acoustic-wave-device manufacturing method according to the second preferred embodiment will be described below. FIG. 16 is an illustration for explaining the manufacturing method according to the second preferred embodiment.

### Piezoelectric-Layer Stacking Step

The hollow 9A and the hollow 9B are formed at a first surface of the support member 8A. Subsequently, the piezoelectric layer 2 is stacked over the first surface of the support member 8A so as to cover the hollow 9A and the hollow 9B.

### Electrode-Film Forming Step

After the piezoelectric-layer stacking step, a film of the first electrode 3 and a film of the second electrode 4 are formed by sputtering or other methods over a first major surface of the piezoelectric layer 2, which is located opposite to the first surface of the support member 8A.

### Attenuation-Layer Forming Step

As illustrated in FIG. 16, after the electrode-film forming step, laser irradiation PL is applied to the second surface of the support member 8A opposite to the first surface. As a result, plasma is generated inside the support member 8A, and a reformed layer with degraded crystallinity is formed. The attenuation layers 10B with a crystallinity different from the crystallinity of the support member 8A are thus provided. The laser irradiation PL is applied for each individual localized area, and the area to be irradiated with laser moves in a scanning direction Scan, which coincides with the Y-direction. In the laser irradiation PL, the area to be irradiated with laser also moves in the X-direction. This results in the attenuation layers 10B being disposed in a dotted manner as seen in the X-Y plane.

In the acoustic-wave-device manufacturing method described above, the piezoelectric-layer stacking step, the electrode-film forming step, and the attenuation-layer forming step are performed in this order. However, in the acoustic-wave-device manufacturing method according to the second preferred embodiment, these steps are not necessarily performed in the above-mentioned order.

### Attenuation-Layer Forming Step

First, with the support member 8A being in the state of a substrate with no hollows 9A and 9B formed therein, laser irradiation PL is applied to the second surface of the support member 8A opposite to the first surface. A portion of the support member 8A that has undergone the laser irradiation PL becomes the attenuation layers 10B that differ in crystallinity from a portion of the support member 8A that does not undergo the laser irradiation PL.

### Piezoelectric-Layer Stacking Step

After the attenuation-layer forming step, the hollow 9A and the hollow 9B are formed at the first surface of the support member 8A. Subsequently, the piezoelectric layer 2 is stacked over the first surface of the support member 8A so as to cover the hollow 9A and the hollow 9B.

### Electrode-Film Forming Step

After the piezoelectric-layer stacking step, a film of the first electrode 3 and a film of the second electrode 4 are formed by sputtering or other methods over a first major surface of the piezoelectric layer 2, which is located opposite to the first surface of the support member 8A.

In the other acoustic-wave-device manufacturing method described above, the attenuation-layer forming step, the piezoelectric-layer stacking step, and the electrode-film forming step are performed in this order. This helps to reduce degradation of the piezoelectric layer 2 or the electrode films at the attenuation-layer forming step, which in turn makes it possible to omit a process for protecting the piezoelectric layer 2 or the electrode films.

FIG. 17 is a cross-sectional view of an acoustic wave device according to a modification of the second preferred embodiment. According to the modification of the second preferred embodiment, the attenuation layers 10B are disposed in only a portion of the support member 8A that overlaps the region NSA3.

For example, a leaky wave LW due to leakage of a wave excited by the electrode 3 of the first resonator RS1 undergoes attenuation in the attenuation layers 10B located in the region NSA3 of the support member 8A. Consequently, a reflected wave LW1 reflected by the attenuation layers 10B undergoes attenuation, which reduces the intensity of the reflected wave LW1 that propagates to the electrode 4 of the second resonator RS2.

### Third Preferred Embodiment

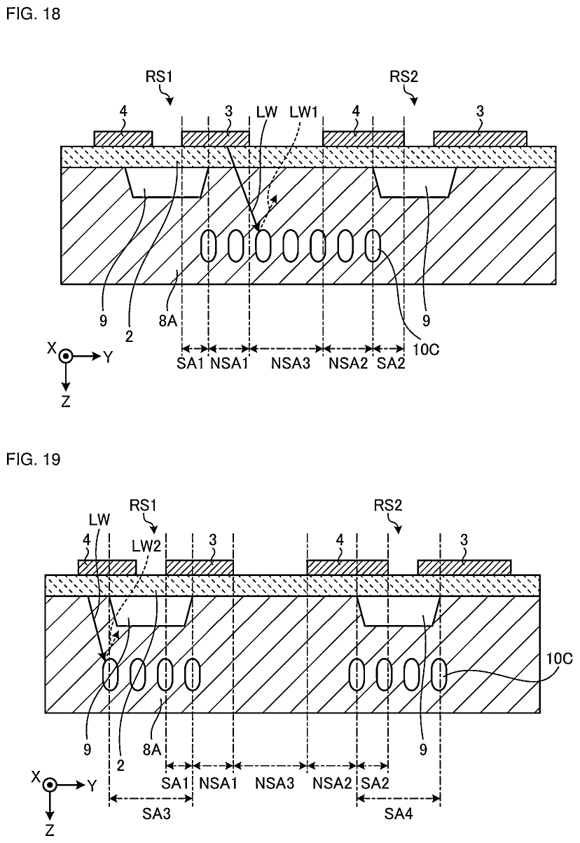

FIG. 18 is a cross-sectional view of an acoustic wave device according to a third preferred embodiment. FIG. 18 illustrates another cross-section taken along the line XII-XII in FIG. 12. Features according to the third preferred embodiment that are identical to those according to the first preferred embodiment will be designated by the same reference signs and will not be described in further detail.

Voids 10C are provided in a portion of the support member 8A that overlaps the region NSA3. According to the third preferred embodiment, the voids 10C are at a depth of greater than or equal to, for example, about 20 μm and less than or equal to about 50 μm from the back side of the support member 8A. The voids 10C are dotted within the region NSA3. It can thus be said that the voids 10C are disposed in a portion of the support member 8A that overlaps the region NSA3.

For example, a leaky wave LW due to leakage of a wave excited by the electrode 3 of the first resonator RS1 undergoes attenuation in the voids 10C located in the region NSA3 of the support member 8A. Consequently, a reflected wave LW1 reflected by the voids 10C undergoes attenuation, which reduces the intensity of the reflected wave LW1 that propagates to the electrode 4 of the second resonator RS2.

FIG. 19 is a cross-sectional view of an acoustic wave device according to a modification of the third preferred embodiment. As illustrated in FIG. 19, as seen in the Z-direction, the voids 10C exist in the region SA3 overlapping the hollow 9A and in the region SA4 overlapping the hollow 9B. For example, a leaky wave LW due to leakage of a wave excited by the electrode 4 of the first resonator RS1 undergoes attenuation in the voids 10C in the region SA3. Consequently, a reflected wave LW2 reflected by the voids 10C undergoes attenuation, which reduces the intensity of the reflected wave LW2 that propagates to the electrode 3 of the first resonator RS1.

### Fourth Preferred Embodiment

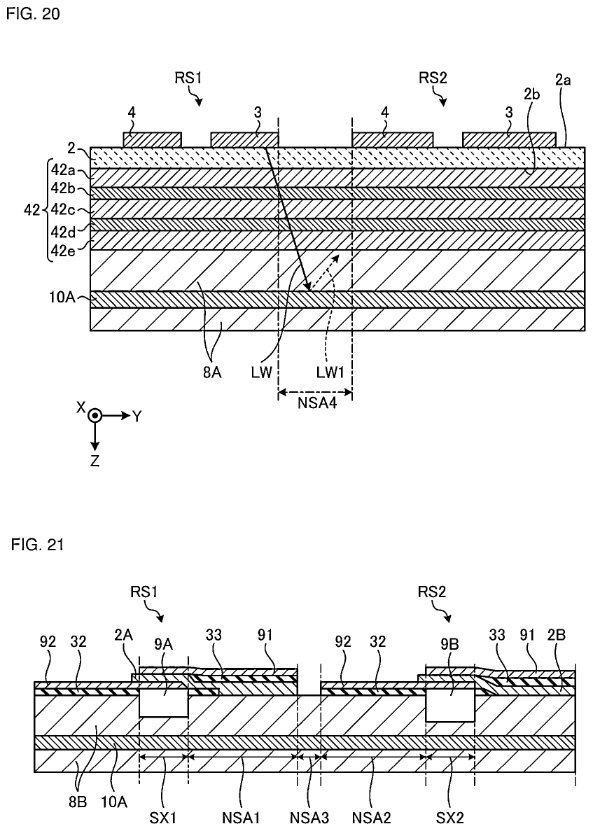

FIG. 20 is a cross-sectional view of an acoustic wave device according to a fourth preferred embodiment. Features according to the fourth preferred embodiment that are identical to those according to the first preferred embodiment will be designated by the same reference signs and will not be described in further detail. In the acoustic wave device according to the fourth preferred embodiment, an acoustic multilayer film 42 is stacked over the second major surface 2b of the piezoelectric layer 2.

The acoustic multilayer film 42 has a multilayer structure including low acoustic impedance layers 42a, 42c, and 42e of relatively low acoustic impedance, and high acoustic impedance layers 42b and 42d of relatively high acoustic impedance. Use of the acoustic multilayer film 42 allows bulk waves in first-order thickness shear mode to be confined within the piezoelectric layer 2 without use of the hollow 9 provided in the acoustic wave device 1. For the acoustic wave device according to the fourth preferred embodiment as well, setting the value of d/p mentioned above to less than or equal to about 0.5, for example, makes it possible to provide resonance characteristics based on bulk waves in first-order thickness shear mode. It is to be noted, however, that in the acoustic multilayer film 42, the number of low acoustic impedance layers to be stacked, and the number of high acoustic impedance layers to be stacked are not particularly limited. It may suffice that at least one high acoustic impedance layer 42b, 42d be positioned farther from the piezoelectric layer 2 than are the low acoustic impedance layers 42a, 42c, 42e.

The low acoustic impedance layers 42a, 42c, and 42e, and the high acoustic impedance layers 42b and 42d may each be made of any suitable material as long as the above-mentioned relationship between their acoustic impedances is satisfied. Examples of suitable materials for the low acoustic impedance layers 42a, 42c, and 42e may include silicon oxide and silicon oxynitride. Examples of suitable materials for the high acoustic impedance layers 42b and 42d may include alumina, silicon nitride, and metal.

As seen in the Z-direction, the region between the first electrode 3 of the first resonator RS1, and the second electrode 4 of the second resonator RS2 is defined as a region NSA4. According to the fourth preferred embodiment, the attenuation layer 10A, which differs in crystallinity from the support member 8A, is disposed in a portion of the support member 8A that overlaps the region NSA4.

For example, a leaky wave LW due to leakage of a wave excited by the electrode 4 of the first resonator RS1 undergoes attenuation in the attenuation layer 10A in the region NSA4. Consequently, a reflected wave LW1 reflected by the attenuation layer 10A undergoes attenuation, which reduces the intensity of the reflected wave LW2 that propagates to the electrode 3 of the first resonator RS1.

### Fifth Preferred Embodiment

FIG. 21 is a cross-sectional view of an acoustic wave device according to a fifth preferred embodiment. Features according to the fifth preferred embodiment that are identical to those according to the first preferred embodiment will be designated by the same reference signs and will not be described in further detail. The acoustic wave device according to the fifth preferred embodiment includes an upper electrode 91, which corresponds to a first electrode, and a lower electrode 92, which corresponds to a second electrode, and piezoelectric layers 2A and 2B. A single support member 8B supports the first resonator RS1 and the second resonator RS2.

The upper electrode 91 and the lower electrode 92 of the first resonator RS1 sandwich the piezoelectric layer 2A in the Z-direction. The upper electrode 91 and the lower electrode 92 of the second resonator RS2 sandwich the piezoelectric layer 2B in the Z-direction. The acoustic wave device according to the fifth preferred embodiment is sometimes also called bulk acoustic wave (BAW) device.

In the acoustic wave device according to the fifth preferred embodiment, the single support member 8B supports the first resonator RS1 and the second resonator RS2. The second resonator RS2 is at a location different from that of the first resonator RS1. The hollow 9A and the hollow 9B, which are provided in the support member 8B, are respectively covered by the piezoelectric layer 2A and the piezoelectric layer 2B. As seen in the Z-direction, the upper electrode 91 and the lower electrode 92 of the first resonator RS1 extend over an overlap region SX1 that overlaps the hollow 9A, and the non-overlap portion NSA1 that does not overlap the hollow 9A. As seen in the Z-direction, the upper electrode 91 and the lower electrode 92 of the second resonator RS2 extend over an overlap region SX2 that overlaps the hollow 9B, and the non-overlap portion NSA2 that does not overlap the hollow 9B. In the non-overlap portions NSA, an insulating film 33 is disposed between the upper electrode 91 and the piezoelectric layer 2A. An insulating film 32 is disposed between the lower electrode 92 and the support member 8B.

The region between the non-overlap portion NSA1 of the upper electrode 91, and the non-overlap portion NSA2 of the lower electrode 92 is defined as the region NSA3. For example, a leaky wave of the wave excited by the upper electrode 91 of the first resonator RS1 undergoes attenuation in the attenuation layer 10A located in the region NSA3 of the support member 8B. Consequently, a reflected wave reflected by the attenuation layer 10A undergoes attenuation, which reduces the intensity of the reflected wave that propagates to the lower electrode 92 of the second resonator RS2.

### Sixth Preferred Embodiment

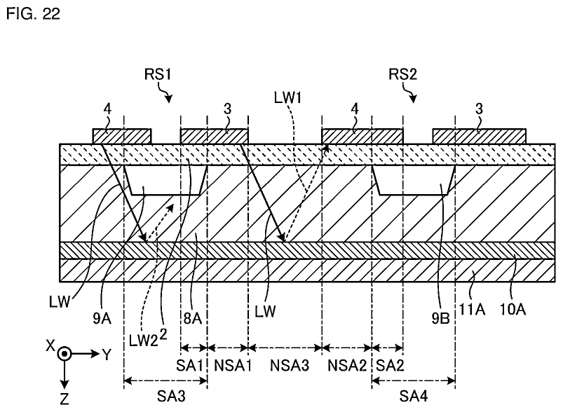

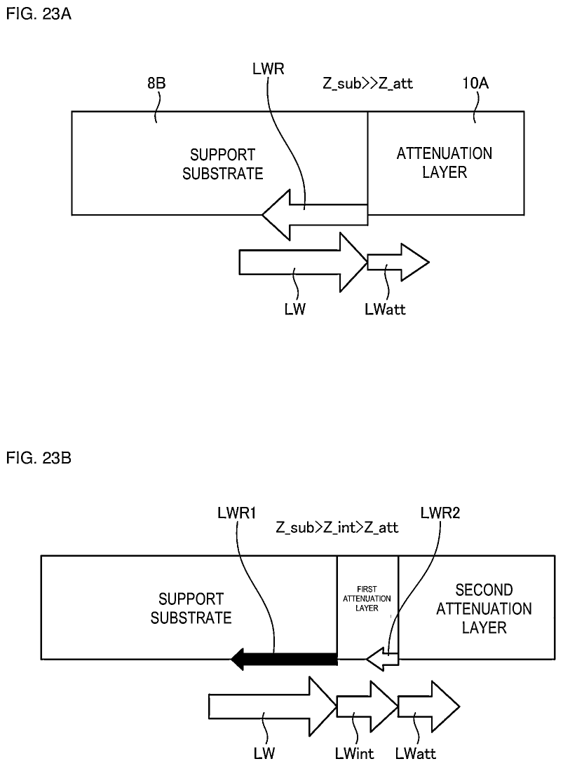

FIG. 22 is a cross-sectional view of an acoustic wave device according to a sixth preferred embodiment. Features according to the sixth preferred embodiment that are identical to those according to the first preferred embodiment will be designated by the same reference signs and will not be described in further detail. According to the sixth preferred embodiment, a first attenuation layer 10A and a second attenuation layer 11A, which differ in crystallinity from the support member 8A, are disposed in a portion of the support member 8A that overlaps the region NSA3. The first attenuation layer 10A is closer to the piezoelectric layer 2 than is the second attenuation layer 11A.

The second attenuation layer 11A differs in material from the first attenuation layer 10A. Alternatively, the second attenuation layer 11A differs in density from the first attenuation layer 10A.

Alternatively, if the support member 8A is made of Si, the first attenuation layer 10A and the second attenuation layer 11A are made of silicon oxide, which is an oxide of Si. As described above, the material of the first attenuation layer 10A, and the material of the second attenuation layer 11A may be of the same kind but differ from each other in density from each other. For example, the first attenuation layer 10A and the second attenuation layer 11A are made to differ from each other in density through changes to the deposition condition or other conditions. For example, the first attenuation layer 10A is made to have a greater density than the second attenuation layer 11A. The second attenuation layer 11A is more porous than the first attenuation layer 10A. Alternatively, if the first attenuation layer 10A and the second attenuation layer 11A are both porous, the first attenuation layer 10A has a density p1 that is greater than a density p2 of the second attenuation layer 11A.

The second attenuation layer 11A may be formed by roughening the back side of the support member 8A. The above-mentioned configuration allows for closer contact of the second attenuation layer 11A with the first attenuation layer 10A, leading to increased adhesion. The above-mentioned configuration also helps to reduce complexity of the manufacturing apparatus for the acoustic wave device, and consequently improve the producibility of the acoustic wave device.

As illustrated in FIG. 22, for example, a leaky wave LW due to leakage of a wave excited by the electrode 3 of the first resonator RS1 undergoes attenuation in the first attenuation layer 10A and the second attenuation layer 11A that are located in the region NSA3 of the support member 8A. Therefore, a reflected wave LW1 reflected by the attenuation layer 10A undergoes attenuation, which reduces the intensity of the reflected wave LW1 that propagates to the electrode 4 of the second resonator RS2.

As seen in the Z-direction, the first attenuation layer 10A and the second attenuation layer 11A exist also in the region SA3, which overlaps the hollow 9A, and the region SA4, which overlaps the hollow 9B. For example, a leaky wave LW due to leakage of a wave excited by the electrode 4 of the first resonator RS1 undergoes attenuation in the attenuation layer 10A in the region SA3. Consequently, a reflected wave LW2 reflected by the attenuation layer 10A undergoes attenuation, which reduces the intensity of the reflected wave LW2 that propagates to the electrode 3 of the first resonator RS1.

FIG. 23A schematically illustrates an acoustic reflected wave according to the first preferred embodiment. FIG. 23B schematically illustrates acoustic reflected waves according to the sixth preferred embodiment. Generally, acoustic impedance decreases with increasing attenuation factor. For example, it is described in Gilbert, S. R., et al. IEEE International Ultrasonics Symposium. IEEE, 2009. with reference to FIG. 4 that acoustic impedance decreases with increasing attenuation factor.

As illustrated in FIG. 23A, if the attenuation layer 10A is a single layer, a leaky wave LW is attenuated within the attenuation layer 10A into a leaky wave LWatt, which is attenuated relative to the leaky wave LW. The support member 8B has an acoustic impedance Z_sub greater than an acoustic impedance Z_att of the attenuation layer 10A. Consequently, a large acoustic Z-ratio between the support member 8A and the attenuation layer 10A may cause an acoustic reflection LWR to occur between the support member 8A and the attenuation layer 10A, which may potentially lead to a limited decrease in ripples.

According to the arrangement illustrated in FIG. 23B, by contrast, the first attenuation layer 10A and the second attenuation layer 11A are arranged in decreasing order of acoustic impedance Z as viewed from the piezoelectric layer. If the acoustic impedance Z_att of the second attenuation layer 11A is equal to the acoustic impedance of the first attenuation layer 10A illustrated in FIG. 23A, a leaky wave LW is attenuated within the first attenuation layer 10A into a leaky wave LWint, which is attenuated relative to the leaky wave LW. The leaky wave LWint is attenuated within the second attenuation layer 11A into a leaky wave LWatt, which is attenuated related to the leaky wave LWint. The acoustic impedance Z_sub of the support member 8A is greater than an acoustic impedance Z_int of the first attenuation layer 10A. The acoustic impedance Z_int of the first attenuation layer 10A is greater than the acoustic impedance Z_att of the second attenuation layer 11A. If the first attenuation layer 10A and the second attenuation layer 11A that differ in material or density from each other are provided, an acoustic reflection LWR2 occurs between the first attenuation layer 10A and the second attenuation layer 11A. This results in reduced acoustic reflection LWR1 between the support member 8A and the attenuation layer 10A, and consequently reduced ripples in frequency characteristics in comparison to a case where a single attenuation layer is provided.

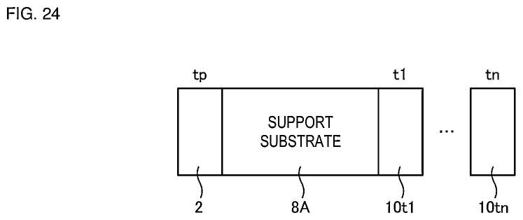

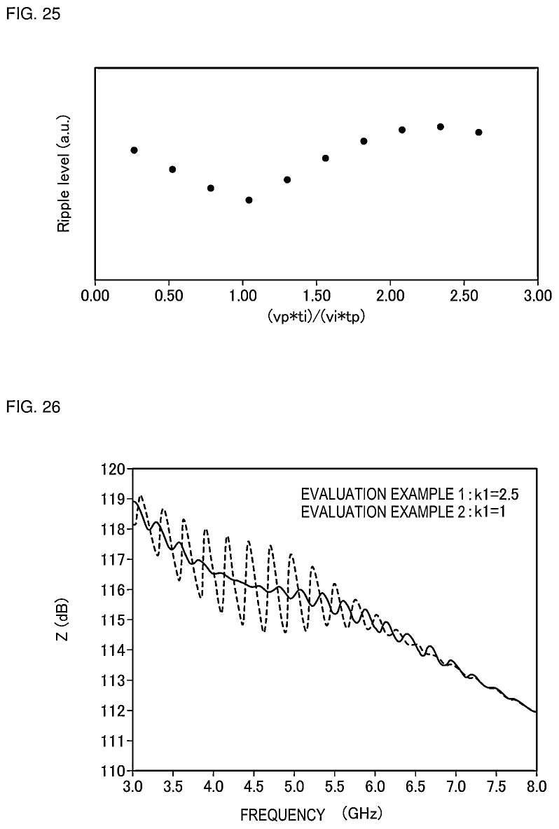

FIG. 24 schematically illustrates attenuation layers of the acoustic wave device according to the sixth preferred embodiment. FIG. 25 is an illustration for explaining, for the acoustic wave device according to the sixth preferred embodiment, the relationship between the thickness of an attenuation layer and ripple level. FIG. 26 is an illustration for explaining acoustic impedance for the acoustic wave device according to the sixth preferred embodiment.

As illustrated in FIG. 24, a model including a stack of a plurality of attenuation layers 10t1 to 10tn is now considered. Since there are a plurality of (n) attenuation layers, it is desirable that the first to (n−1)-th layers be optimized in thickness to reduce acoustic reflection. To reduce ripples in a frequency band where thickness shear resonance occurs, it is desirable that a ratio ki satisfies Expression (1) and Expression (2) below, where ti is the thickness of an attenuation layer 10ti (i is an integer from 1 to n), vi is the transverse-wave acoustic velocity of the attenuation layer 10ti, vp is the transverse-wave acoustic velocity of the piezoelectric layer 2, and tp is the thickness of the piezoelectric layer.

ki=(vp/vi)×(ti/tp) (1)

0.8≤ki≤1.2 (2)

FIG. 25 illustrates a simulated case where a first attenuation layer 10t1 is made of silicon oxide and a second attenuation layer 10t2 is made of polymer, with the maximum value of ripple due to the first attenuation layer 10t1 plotted on the vertical axis and the above-mentioned ratio ki plotted on the horizontal axis. The polymer of the second attenuation layer 10t2 is polyimide.

FIG. 26 illustrates a comparison between Evaluation Example 1 and Evaluation Example 2. Evaluation Example 1 represents changes in Z-parameter with respect to frequency when k1=2.5. Evaluation Example 2 represents changes in Z-parameter with respect to frequency when k1=1. As illustrated in FIGS. 25 and 26, desirably, ki satisfies Expression (2) above, and more desirably, ki=1.

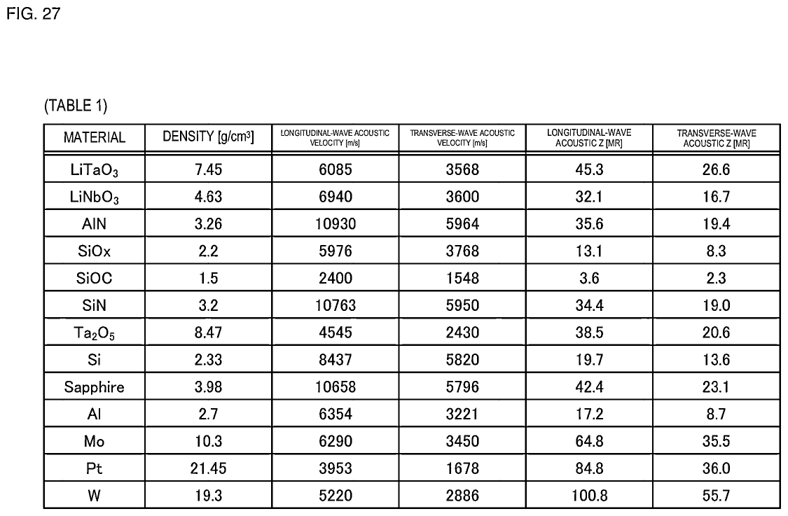

FIG. 27 is an illustration for explaining, for the acoustic wave device according to the sixth preferred embodiment, the relationship between the material of an attenuation layer and transverse-wave acoustic velocity. The material of the piezoelectric layer 2, and the material of the attenuation layer 10tn are selected based on, for example, the values of transverse-wave acoustic velocity in Table 1 illustrated in FIG. 27. For example, if the support member 8A, which corresponds to a support substrate, is made of Si, and the first attenuation layer 10t1 is made of silicon oxide (SiOx), then SiOC is selected as the material of the second attenuation layer 10t2.

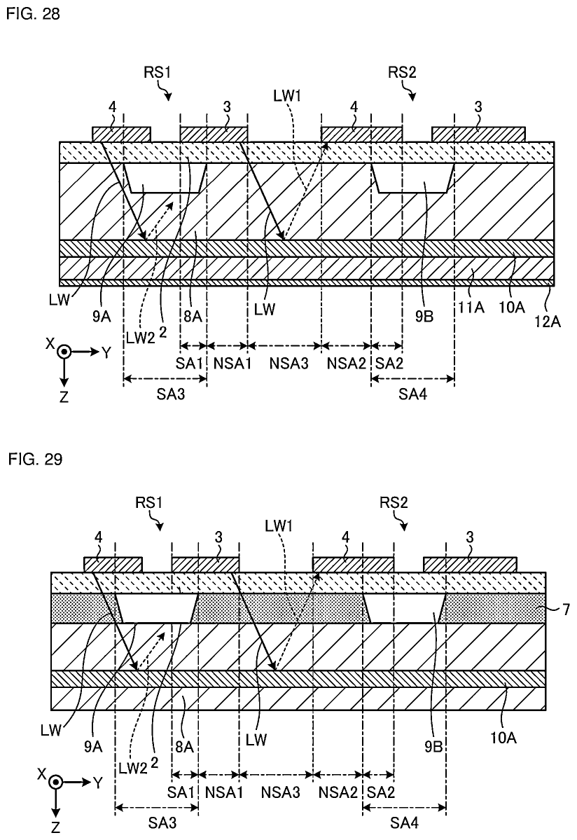

FIG. 28 is a cross-sectional view of an acoustic wave device according to a modification of the sixth preferred embodiment. According to the modification of the sixth preferred embodiment, the first attenuation layer 10A, the second attenuation layer 11A, and a third attenuation layer 12A are lower in acoustic impedance than the support member 8A, which corresponds to a support substrate. Further, the second attenuation layer 11A is made to differ in acoustic impedance from the first attenuation layer 10A. The second attenuation layer 11A is lower in acoustic impedance than the first attenuation layer 10A. The third attenuation layer 12A is made to differ in acoustic impedance from the second attenuation layer 11A. Although it is desirable that the third attenuation layer 12A be lower in acoustic impedance than the second attenuation layer 11A, the third attenuation layer 12A may be higher in acoustic impedance than the second attenuation layer 11A.

For example, a leaky wave LW due to leakage of a wave excited by the electrode 3 of the first resonator RS1 undergoes attenuation in the first attenuation layer 10A, the second attenuation layer 11A, and the third attenuation layer 12A that are located in the region NSA3 of the support member 8A. Therefore, a reflected wave LW1 reflected by the attenuation layer 10A undergoes attenuation, which reduces the intensity of the reflected wave LW1 that propagates to the electrode 4 of the second resonator RS2.

As seen in the Z-direction, the first attenuation layer 10A, the second attenuation layer 11A, and the third attenuation layer 12A exist also in the region SA3 that overlaps the hollow 9A, and in the region SA4 that overlaps the hollow 9B. For example, a leaky wave LW due to leakage of a wave excited by the electrode 4 of the first resonator RS1 undergoes attenuation in the attenuation layer 10A in the region SA3. Consequently, a reflected wave LW2 reflected by the attenuation layer 10A undergoes attenuation, which reduces the intensity of the reflected wave LW2 that propagates to the electrode 3 of the first resonator RS1.

### Seventh Preferred Embodiment

FIG. 29 is a cross-sectional view of an acoustic wave device according to a modification of a seventh preferred embodiment. In the acoustic wave device according to the seventh preferred embodiment, a single support member 8A supports the first resonator RS1 and the second resonator RS2. The second resonator RS2 is at a location different from that of the first resonator RS1. Unlike in the acoustic wave device according to the first preferred embodiment, in the acoustic wave device according to the seventh preferred embodiment, the hollow 9A and the hollow 9B are provided in the intermediate layer 7. Features according to the seventh preferred embodiment that are identical to those according to the first preferred embodiment will be designated by the same reference signs and will not be described in further detail.

According to the seventh preferred embodiment, the presence of the hollow 9A and the hollow 9B in the intermediate layer 7 makes it possible to increase the accuracy of a membrane region of the piezoelectric layer 2 that overlaps the hollow 9A and the hollow 9B. The hollow 9A and the hollow 9B each correspond to a space defined by an air gap provided between the support member 8A and the piezoelectric layer 2. According to the seventh preferred embodiment, the piezoelectric layer 2 may, in some cases, be provided with a hole for forming each of the hollow 9A and the hollow 9B. The piezoelectric layer 2 covers the hollow 9A and the hollow 9B except at the location of this hole. As described above, at least part of the hollow 9A, and at least part of the hollow 9B are covered by the piezoelectric layer 2.

For example, a leaky wave LW due to leakage of a wave excited by the electrode 3 of the first resonator RS1 undergoes attenuation in the first attenuation layer 10A located in the region NSA3 of the support member 8A. Therefore, a reflected wave LW1 reflected by the attenuation layer 10A undergoes attenuation, which reduces the intensity of the reflected wave LW1 that propagates to the electrode 4 of the second resonator RS2.

As seen in the Z-direction, the first attenuation layer 10A exists also in the region SA3, which overlaps the hollow 9A, and in the region SA4, which overlaps the hollow 9B. For example, a leaky wave LW due to leakage of a wave excited by the electrode 4 of the first resonator RS1 undergoes attenuation in the attenuation layer 10A in the region SA3. Consequently, a reflected wave LW2 reflected by the attenuation layer 10A undergoes attenuation, which reduces the intensity of the reflected wave LW2 that propagates to the electrode 3 of the first resonator RS1.

### Eighth Preferred Embodiment

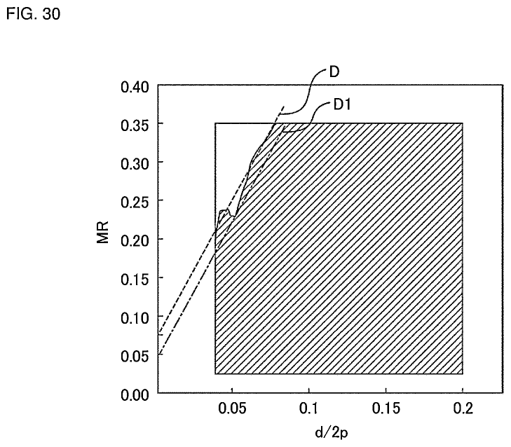

FIG. 30 is an illustration for explaining, for an acoustic wave device according to an eighth preferred embodiment, the relationship between d/2p, metallization ratio MR, and fractional band width. Features according to the eighth preferred embodiment that are identical to those according to the first preferred embodiment will be designated by the same reference signs and will not be described in further detail. As the acoustic wave device 1 according to the eighth preferred embodiment, acoustic wave devices 1 with different values of d/2p and MR are formed, and their fractional band widths are measured. The hatched region on the right-hand side of a broken line D in FIG. 30 represents a region with a fractional bandwidth of less than or equal to about 17%. The boundary between the hatched region and a non-hatched region is represented as MR=about 3.5(d/2p)+0.075. That is, MR=about 1.75(d/p)+0.075. Accordingly, it is preferable that MR≤about 1.75(d/p)+0.075, for example. In that case, a fractional band width of less than or equal to about 17% can be easily obtained. A more preferable example of the above-mentioned region is the region on the right-hand side of an alternate long and short dashed line D1 in FIG. 30 that represents MR=about 3.5(d/2p)+0.05. In other words, if MR about 1.75(d/p)+0.05, this allows a fractional band width of less than or equal to about 17% to be obtained with reliability.

### Ninth Preferred Embodiment

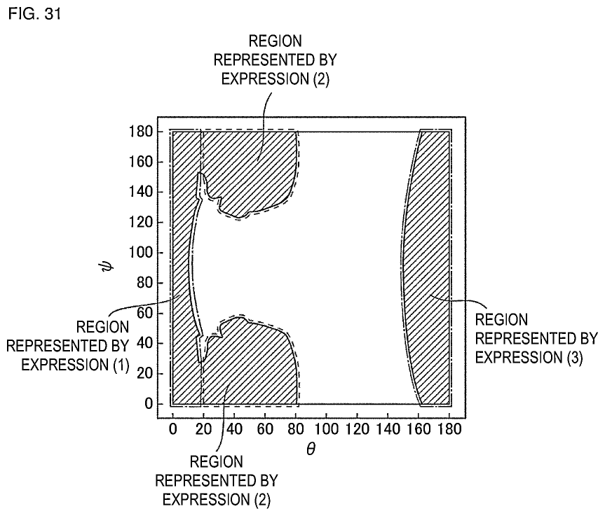

FIG. 31 illustrates, for an acoustic wave device according to a ninth preferred embodiment, a map of fractional band width with respect to the Euler angles (0°, θ, ψ) of LiNbO₃ with d/p set as close to zero as possible. Features according to the ninth preferred embodiment that are identical to those according to the first preferred embodiment will be designated by the same reference signs and will not be described in further detail. Hatched regions in FIG. 31 represent regions where a fractional band width of at least greater than or equal to about 5% is obtained. The ranges of individual regions are approximated by Expressions (3), (4), and (5) below.

(0°±10°,0° to 20°,any ψ) (3)

(0°±10°,20° to 80°,0° to 60°(1−(θ−50)²/900)^{1/2}) or(0°±10°,20° to 80°,[180°−60°(1−(θ−50)²/900)^{1/2}] to 180°) (4)

(0°±10°,[180°−30°(1−(ψ−90)²/8100)^{1/2}] to 180°,any ψ) (5)

Therefore, Euler angles within the range represented by Expression (3), (4), or (5) are preferred from the viewpoint of achieving a sufficiently large fractional band width.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support substrate;
a piezoelectric layer overlapping the support substrate as seen in a first direction; and
a first electrode and a second electrode that extend over at least a first major surface of the piezoelectric layer, the first electrode and the second electrode facing each other and being at mutually different potentials; wherein
a space exists between a second major surface of the piezoelectric layer, and the support substrate, the second major surface being opposite to the first major surface;
the space is at least partially covered by the piezoelectric layer;
the first electrode and the second electrode each include an overlap portion and a non-overlap portion, the overlap portion overlapping the space in the first direction, the non-overlap portion not overlapping the space in the first direction; and
at least part of the support substrate includes an attenuation layer, the at least part of the support substrate overlapping a region between the non-overlap portion of the first electrode and the non-overlap portion of the second electrode in plan view, the attenuation layer having a crystallinity different from a crystallinity of the support substrate.

2. An acoustic wave device comprising:
a support substrate;
a piezoelectric layer overlapping the support substrate as seen in a first direction;
a first resonator extending over at least a first major surface of the piezoelectric layer; and
a second resonator extending over at least the first major surface of the piezoelectric layer, the second resonator being at a location different from a location of the first resonator; wherein
the first resonator includes:
a first space opposite to the first major surface and at or adjacent to a second major surface of the piezoelectric layer; and
a first electrode including a first overlap portion and a first non-overlap portion, the first overlap portion overlapping the first space in the first direction, the first non-overlap portion not overlapping the first space in the first direction;
the second resonator includes:
a second space opposite to the first major surface and at or adjacent to the second major surface of the piezoelectric layer; and
a second electrode including a second overlap portion and a second non-overlap portion, the second overlap portion overlapping the second space in the first direction, the second non-overlap portion not overlapping the second space in the first direction;
the second space is at a location different from a location of the first space;
the first electrode and the second electrode face each other, and are at mutually different potentials; and
at least part of the support substrate includes an attenuation layer, the at least part of the support substrate overlapping a region between the first non-overlap portion and the second non-overlap portion in plan view, the attenuation layer having a crystallinity different from a crystallinity of the support substrate.

3. The acoustic wave device according to claim 1, wherein the attenuation layer includes an amorphous silicon layer or a polysilicon layer.

4. The acoustic wave device according to claim 1, wherein the attenuation layer is inside the support substrate.

5. The acoustic wave device according to claim 1, wherein the attenuation layer includes a first attenuation layer and a second attenuation layer.

6. The acoustic wave device according to claim 5, wherein the second attenuation layer differs in material from the first attenuation layer that is closer to the piezoelectric layer than is the second attenuation layer.

7. The acoustic wave device according to claim 5, wherein the second attenuation layer differs in density from the first attenuation layer that is closer to the piezoelectric layer than is the second attenuation layer.

8. The acoustic wave device according to claim 7, wherein each of the first attenuation layer and the second attenuation layer is an oxide film that is an oxide of a material of the support substrate.

9. The acoustic wave device according to claim 5, wherein the second attenuation layer has a smaller acoustic impedance than the first attenuation layer that is closer to the piezoelectric layer than is the second attenuation layer.

10. The acoustic wave device according to claim 5, wherein a ratio ki satisfies Expression (1) and Expression (2), where Vi is a transverse-wave acoustic velocity of the first attenuation layer, ti is a thickness of the first attenuation layer, vp is a transverse-wave acoustic velocity of the piezoelectric layer, and tp is a thickness of the piezoelectric layer:
ki=(vp/vi)×(ti/tp) (1)
0.8≤ki≤1.2 (2).

11. The acoustic wave device according to claim 10, wherein the ratio ki is 1.

12. The acoustic wave device according to claim 5, wherein one of the first attenuation layer and the second attenuation layer is made of a material including SiOx or SiOC.

13. The acoustic wave device according to claim 5, wherein one of the first attenuation layer and the second attenuation layer is made of a material including a polymer.

14. The acoustic wave device according to claim 1, wherein the support substrate is made of a material including Si.

15. The acoustic wave device according to claim 1, wherein the piezoelectric layer includes lithium niobate or lithium tantalate.

16. The acoustic wave device according to claim 1, wherein the piezoelectric layer includes lithium niobate or lithium tantalate; and
d/p≤0.5, where d is a thickness of the piezoelectric layer, and p is a center-to-center distance between the first electrode and the second electrode that are adjacent to each other.

17. The acoustic wave device according to claim 2, wherein
the piezoelectric layer includes lithium niobate or lithium tantalate;
the first resonator includes the first electrode of the first resonator and a second electrode of the first resonator that are adjacent to each other;
and
d/p≤0.5, where d is a thickness of the piezoelectric layer, and p is a center-to-center distance between the first electrode of the first resonator and the second electrode of the first resonator that are adjacent to each other.

18. The acoustic wave device according to claim 15, wherein the first electrode and the second electrode are IDT electrodes.

19. The acoustic wave device according to claim 1, wherein a metallization ratio MR satisfies MR≤1.75(d/p)+0.075, the metallization ratio MR being a ratio of an area of the first electrode and the second electrode within an excitation region to the excitation region, the excitation region being a region where the first electrode and the second electrode overlap each other as seen in a direction in which the first electrode and the second electrode face each other.

20. The acoustic wave device according to claim 1, wherein
the piezoelectric layer includes lithium niobate or lithium tantalate; and
the lithium niobate or lithium tantalate has Euler angles (φ, θ, ψ) within a range represented by Expression (4), Expression (5), or Expression (6):
(0°±10°,0° to 20°,any ψ) (4)
(0°±10°,20° to 80°,0° to 60°(1−(θ−50)²/900)^{1/2}) or(0°±10°,20° to 80°,[180°−60°(1−(θ−50)²/900)^{1/2}] to 180°) (5)
(0°±10°,[180°−30°(1−(ψ−90)²/8100)^{1/2}] to 180°,any ψ) (6)

21. An acoustic-wave-device manufacturing method comprising:
forming an attenuation layer inside a support substrate including a first surface and a second surface, the attenuation layer having a crystallinity different from a crystallinity of the support substrate, the attenuation layer being formed by ion implantation applied to the second surface of the support substrate;
stacking a piezoelectric layer over the first surface of the support substrate such that the piezoelectric layer covers a hollow provided in the support substrate; and
forming a first electrode film and a second electrode film over a surface of the piezoelectric layer opposite to the first surface of the support substrate; wherein
the forming the attenuation-layer, the stacking the piezoelectric-layer, and the forming the electrode-film are performed in this order.

22. An acoustic-wave-device manufacturing method comprising:
forming an attenuation layer inside a support substrate including a first surface and a second surface, the attenuation layer having a crystallinity different from a crystallinity of the support substrate, the attenuation layer being formed by laser irradiation applied to the second surface of the support substrate;
stacking a piezoelectric layer over the first surface of the support substrate such that the piezoelectric layer covers a hollow provided in the support substrate; and
forming a first electrode film and a second electrode film over a surface of the piezoelectric layer opposite to the first surface of the support substrate; wherein
the forming the attenuation-layer, the stacking the piezoelectric-layer, and the forming the electrode-film are performed in this order.

23. The acoustic-wave-device manufacturing method according to claim 21, wherein the attenuation layer includes an amorphous silicon layer or a polysilicon layer.

24. An acoustic wave device comprising:
a support substrate;
a piezoelectric layer overlapping the support substrate as seen in a first direction; and
a first electrode and a second electrode extending over at least a first major surface of the piezoelectric layer, the first electrode and the second electrode facing each other and being at mutually different potentials; wherein
a space exists between a second major surface of the piezoelectric layer, and the support substrate, the second major surface being opposite to the first major surface;
the space is at least partially covered by the piezoelectric layer;
the first electrode and the second electrode each include an overlap portion and a non-overlap portion, the overlap portion overlapping the space in the first direction, the non-overlap portion not overlapping the space in the first direction; and
at least part of the support substrate includes a void, the at least part of the support substrate overlapping a region between the non-overlap portion of the first electrode and the non-overlap portion of the second electrode in plan view, the void being defined by a partially hollowed out portion of the support substrate.

25. An acoustic wave device comprising:
a support substrate;
a piezoelectric layer overlapping the support substrate as seen in a first direction;
a first resonator extending over at least a first major surface of the piezoelectric layer; and
a second resonator extending over at least the first major surface of the piezoelectric layer, the second resonator being at a location different from a location of the first resonator;
wherein the first resonator includes:
a first space opposite to the first major surface and at or adjacent to a second major surface of the piezoelectric layer; and
a first electrode including a first overlap portion and a first non-overlap portion, the first overlap portion overlapping the first space in the first direction, the first non-overlap portion not overlapping the first space in the first direction;
the second resonator includes:
a second space opposite to the first major surface and at or adjacent to the second major surface of the piezoelectric layer; and
a second electrode including a second overlap portion and a second non-overlap portion, the second overlap portion overlapping the second space in the first direction, the second non-overlap portion not overlapping the second space in the first direction;
the second space is at a location different from a location of the first space;
the first electrode and the second electrode face each other, and are at mutually different potentials; and
at least part of the support substrate includes a void, the at least part of the support substrate overlapping a region between the first non-overlap portion and the second non-overlap portion in plan view, the void being defined by a partially hollowed out portion of the support substrate.
